(19) United States
(12) Patent Application Publication
(10) Pub. No.: US 2015/0200516 A1
(43) Pub. Date: Jul. 16, 2015

(54) LATCH RELEASE TOOL

(71) Applicant: Wistron Corporation, New Taipei City (TW)

(72) Inventor: Ling-Hui Zeng, New Taipei City (TW)

(21) Appl. No.: 14/296,427

(22) Filed: Jun. 4, 2014

(30) Foreign Application Priority Data
Jan. 10, 2014 (CN) 201410012508.3

(51) Int. Cl. H01R 43/26; H05K 13/04; H05K 13/00

(52) U.S. Cl. CPC H01R 43/26; H05K 13/0007; H05K 13/0491

(57) ABSTRACT

A latch release tool for releasing memory slot devices of a main board includes a baseboard, first and second strip blocks, first and second driving blocks, and first and second handles. Each memory slot device includes first and second latches. The first and second strip blocks are movably disposed on the baseboard. The first driving block is movably disposed between the first and second strip blocks. The second driving block is movably disposed between the first driving block and the second strip block. The first and second handles pivoted to each other are inserted into the first and second driving blocks respectively. When force acts on the first and second handles, the first and second handles rotate relatively to push the first and second driving blocks respectively, so as to drive the first and second strip blocks to release each first latch and each second latch respectively.

### BACKGROUND OF THE INVENTION

1. Field of the Invention

The present invention relates to a latch release tool, and more specifically, to a latch release tool for releasing a plurality of memory slot devices of a main board.

2. Description of the Prior Art

In general, a main board usually has a plurality of memory slot devices (e.g. Dual In-Line Memory Module, DIMM) disposed thereon for installation of memory devices. Each memory slot device adopts the design in which two latches are pivoted to two sides of a strip slot, so that the a memory device could be inserted into or detached from the strip slot when the two latches rotate outward to a release position or could be engaged with the strip slot when the two latches rotate inward to a lock position. The conventional operation for releasing the two latches of each memory slot device is to sequentially push the two latches of each memory slot device to the release position by a user's fingers. However, it is time-consuming and strenuous for the user to manually perform the latch release operation of the main board, so as to cause the user much inconvenience in installation of a memory device. Furthermore, it may also cause the problem that the memory slot device could damage easily due to excessive force exerted by the user as well as the problem that the user's fingers could be cut by the memory slot device accidentally due to the improper operation of the user.

### SUMMARY OF THE INVENTION

An objective of the present invention is to provide a latch release tool for releasing a plurality of memory slot devices of a main board, to solve the aforesaid problem.

The present invention provides a latch release tool for releasing a plurality of memory slot devices of a main board. Each memory slot device includes a strip slot, a first latch, and a second latch. The first latch and the second latch are pivoted to two ends of the strip slot respectively. The latch release tool includes a baseboard, a first strip block, a second strip block, a first driving block, a second driving block, a first handle, and a second handle. The baseboard has a first side and a second side opposite to the first side. The first strip block is movably disposed on the first side of the baseboard. The second strip block is movably disposed on the second side of the baseboard. The first driving block is movably disposed between the first strip block and the second strip block and is connected to the first strip block. The second driving block is movably disposed between the first driving block and the second strip block and is connected to the second strip block. The first handle has a first force applying end and a first driving end. The first driving end is inserted into the first driving block. The second handle is pivoted to the first handle and has a second force applying end and a second driving end. The second driving end is inserted into the second driving block. The first driving end and the second driving end respectively push the first driving block and the second driving block to move outward when the baseboard is placed on each strip slot and force acts on the first force applying end and the second force applying end to make the first handle and the second handle rotate relatively, for driving the first strip block and the second strip block to respectively push each first latch and each second latch so that each first latch and each second latch could rotate from a lock position to a release position.

According to the claimed invention, the latch release tool further includes a first spring. The first spring is connected to the first handle and the second handle. The first spring is for providing elastic force to make the first force applying end and the second force applying end away from each other and to make the first driving end and the second driving end respectively pull the first driving block and the second driving block to move inward, so as to drive the first strip block and the second strip block to separate from each first latch and each second latch respectively.

According to the claimed invention, the latch release tool further includes at least one second spring. The at least one second spring is connected to the first strip block and the second strip block for providing elastic force to pull the first strip block and the second strip block to move inward, so as to make the first strip block and the second strip block separate from each first latch and each second latch respectively.

According to the claimed invention, the latch release tool further includes at least one limiting block. The at least one limiting block is disposed on the baseboard and is located between the first strip block and the second strip block for abutting against the first strip block and the second strip block when the first strip block and the second strip block move inward.

According to the claimed invention, the at least one limiting block has a slot hole.

According to the claimed invention, the at least one limiting block is made of bakelite material.

According to the claimed invention, the first driving block and the second driving block are a T-shaped block respectively.

According to the claimed invention, the first driving block and the second driving block are movably disposed on the baseboard in a shaft-hole fitting manner.

According to the claimed invention, the first driving block and the second driving block are made of aluminum alloy material.

According to the claimed invention, the first strip block and the second strip block are movably disposed on the baseboard in a shaft-hole fitting manner.

According to the claimed invention, the baseboard, the first strip block, the second strip block, the first handle, and the second handle are made of bakelite material.

In summary, compared with the prior art in which the user must utilize his fingers to push each latch to the release position, the present invention utilizes the linkage mechanism composed of the handles, the driving blocks, and the strip blocks, to make the driving blocks move outward with rotation of the handles, so that the strip blocks could push the latches from the lock position to the release position. In such a manner, it is time-saving and effortless for the user to release the memory slot devices on the main board by utilizing the latch release tool provided by the present invention, so as to improve convenience of the main board in installation of the memory devices. Furthermore, since the present invention does not require the user to utilize his fingers to push the latches, the latch release tool provided by the present invention could further solve the prior art problem that the memory slot device could damage easily due to excessive force exerted by the user, and could effectively prevent the user's fingers from being cut by the memory device accidentally.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded diagram of a latch release tool according to an embodiment of the present invention.

FIG. 2 is an assembly diagram of the latch release tool in FIG. 1.

FIG. 3 is a diagram of the latch release tool in FIG. 2 being placed on a plurality of memory slot devices on a main board.

FIG. 4 is a side view of the latch release tool in FIG. 3 being placed on the main board.

FIG. 5 is a side view of a first strip block and a second strip block in FIG. 4 pushing a first latch and a second latch to a release position respectively.

FIG. 6 is a diagram of the first strip block and the second strip block in FIG. 5 being separate from the first latch and the second latch respectively.

### DETAILED DESCRIPTION

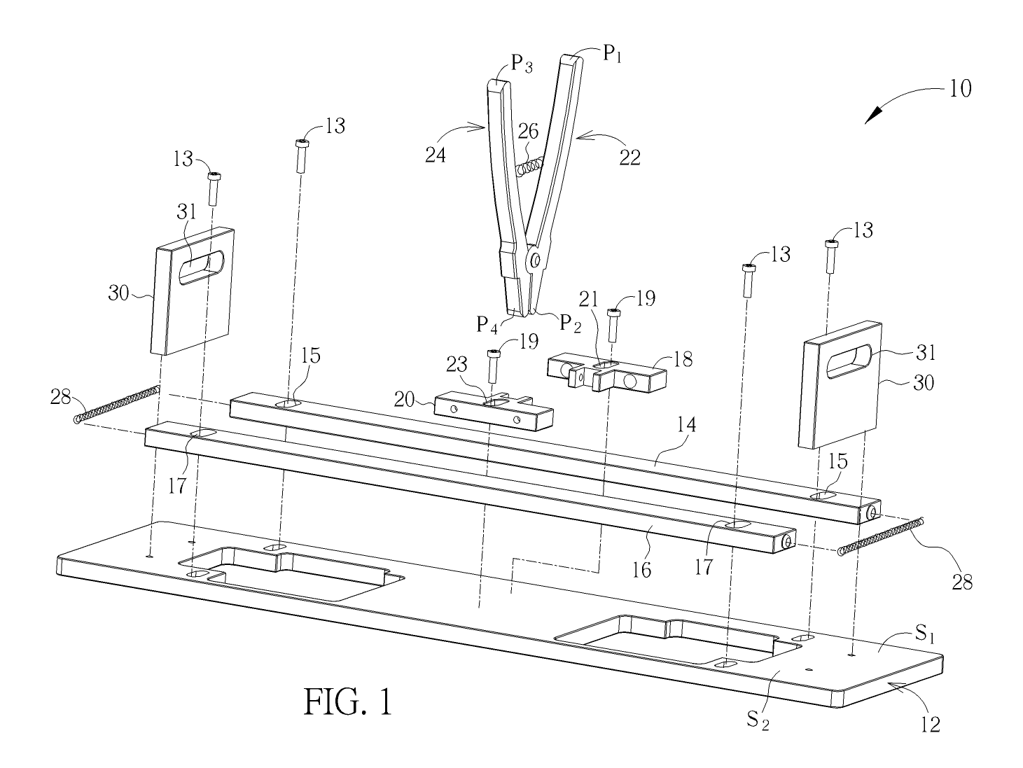

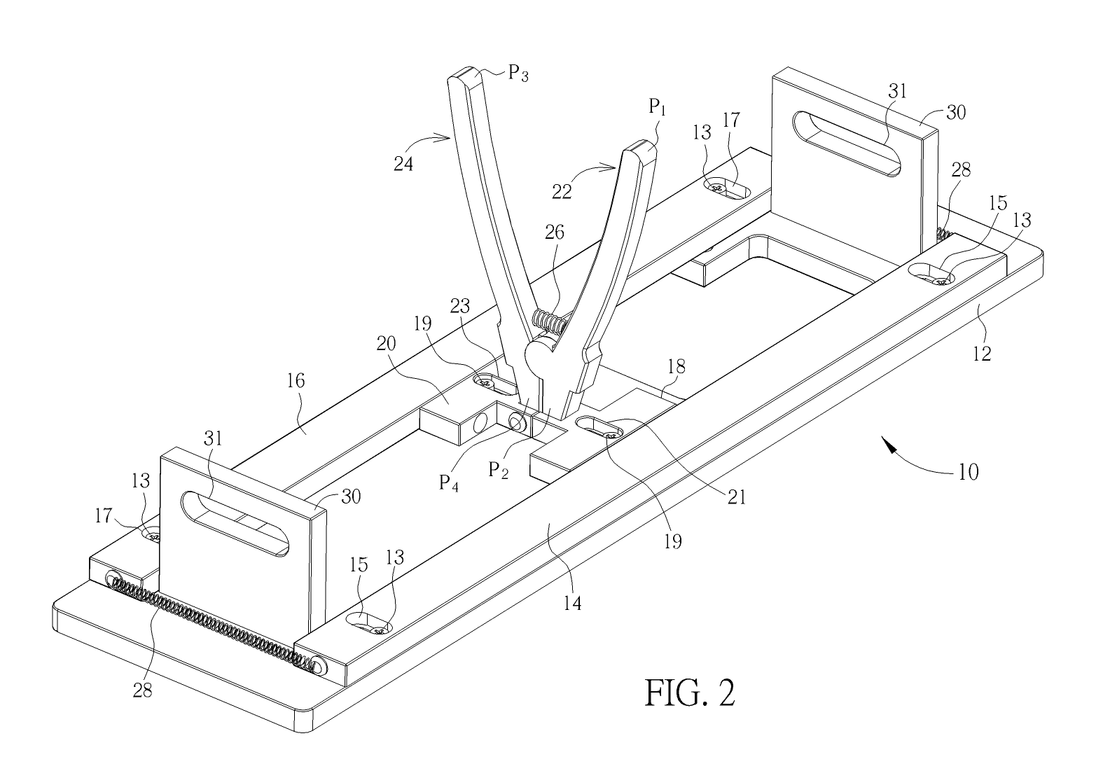

Please refer to FIG. 1 and FIG. 2. FIG. 1 is an exploded diagram of a latch release tool 10 according to an embodiment of the present invention. FIG. 2 is an assembly diagram of the latch release tool 10 in FIG. 1. The latch release tool 10 is used for releasing a plurality of memory slot devices on a main board. As shown in FIG. 1 and FIG. 2, the latch release tool 10 includes a baseboard 12, a first strip block 14, a second strip block 16, a first driving block 18, a second driving block 20, a first handle 22, and a second handle 24. The baseboard 12 could be preferably made of bakelite material (but not limited thereto) and has a first side S₁ and a second side S₂ opposite to the first side S₁. The first strip block 14 and the second strip block 16 could be preferably made of bakelite material, but not limited thereto. The first strip block 14 is movably disposed on the first side S₁ of the baseboard 12, and the second strip block 16 is movably disposed on the second side S₂ of the baseboard 12. To be more specific, in this embodiment, the first strip block 14 and the second strip block 16 are movably disposed on the baseboard 12 in a shaft-hole fitting manner (but not limited thereto). For example, as shown in FIG. 1, the latch release tool 10 could utilize four screws 13 (but not limited thereto) to pass through two limiting slots 15 of the first strip block 14 and two limiting slots 17 of the second strip block 16 respectively.

The first driving block 18 is movably disposed between the first strip block 14 and the second strip block 16 and is connected to the first strip block 14. The second driving block 20 is movably disposed between the first driving block 18 and the second strip block 16 and is connected to the second strip block 16. The first driving block 18 and the second driving block 20 are preferably made of aluminum alloy material (but not limited thereto). Similarly, in this embodiment, the first driving block 18 and the second driving block 20 are movably disposed on the baseboard 12 in a shaft-hole fitting manner (but not limited thereto). For example, as shown in FIG. 1, the latch release tool 10 could utilize two screws 19 (but not limited thereto) to pass through a limiting slot 21 of the first driving block 18 and a limiting slot 23 of the second driving block 20 respectively. Furthermore, the first driving block 18 and the second driving block 20 are preferably a T-shaped block for further increasing the contact area between the first driving block 18 and the first strip block 14 and the contact area between the second driving block 20 and the second strip block 16, so that the first driving block 18 and the second driving block 20 could exert force upon the first strip block 14 and the second strip block 16 more evenly to make the first strip block 14 and the second strip block 16 move smoothly.

The first handle 22 and the second handle 24 could be preferably made of bakelite material (but not limited thereto). The first handle 22 has a first force applying end P₁ and a first driving end P₂. The first driving end P₂ is inserted into the first driving block 18. The second handle 24 is pivoted to the first handle 22 and has a second force applying end P₃ and a second driving end P₄. The second driving end P₄ is inserted into the second driving block 20. Accordingly, the first driving block 18 and the second driving block 20 could move outward or inward with rotation of the first handle 22 and the second handle 24.

Furthermore, as shown in FIG. 1 and FIG. 2, in this embodiment, the latch release tool 10 could further include a first spring 26 and at least one second spring 28 (two shown in FIG. 1 and FIG. 2 respectively, but not limited thereto). The first spring 26 is connected to the first handle 22 and the second handle 24 for providing elastic force to make the first handle 22 and the second handle 24 capable of returning back to the original position automatically. Similarly, the second spring 28 is connected to the first strip block 14 and the second strip block 16 for providing elastic force to make the first strip block 14 and the second strip block 16 capable of returning back to the original position automatically.

Furthermore, in this embodiment, the latch release tool 10 could further include at least one limiting block 30 (two shown in FIG. 1 and FIG. 2 respectively, but not limited thereto). The limiting block 30 could be preferably made of bakelite material. The limiting block 30 is disposed on the baseboard 12 and is located between the first strip block 14 and the second strip block 16 for abutting against the first strip block 14 and the second strip block 16 when the first strip block 14 and the second strip block 16 move inward. In practical application, the limiting block 30 could have a slot hole 31 so that a user could grasp the limiting block 30 conveniently via the slot hole 31 for placing or lifting the latch release tool 10.

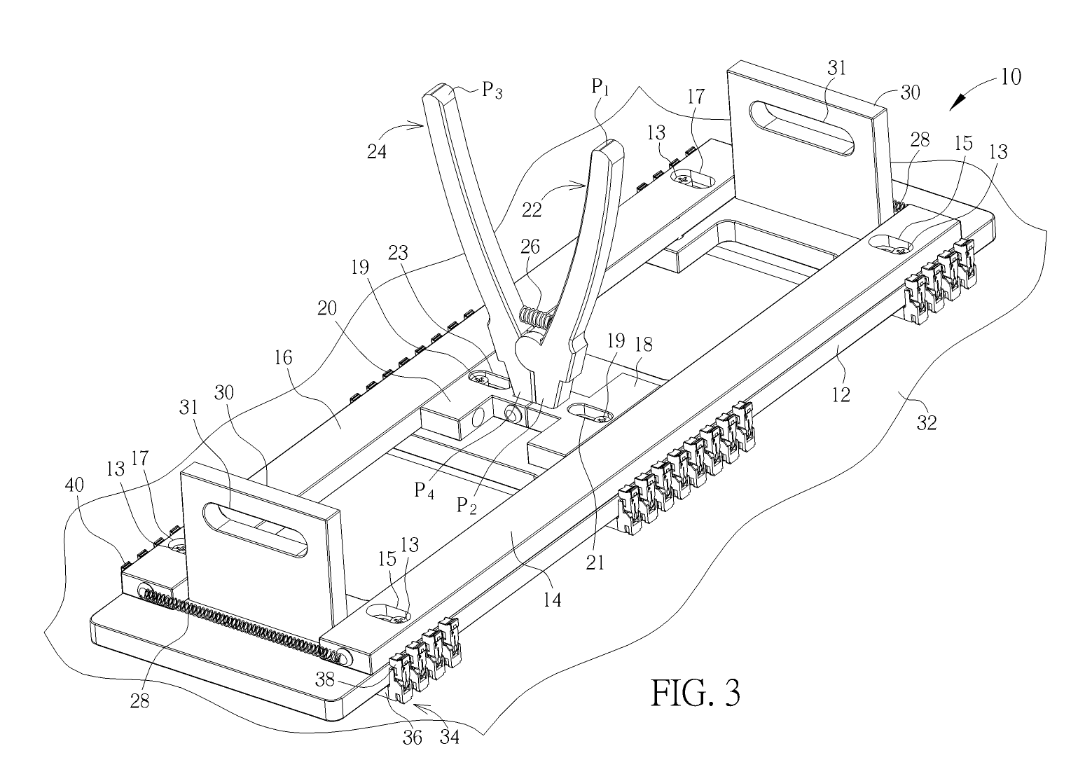

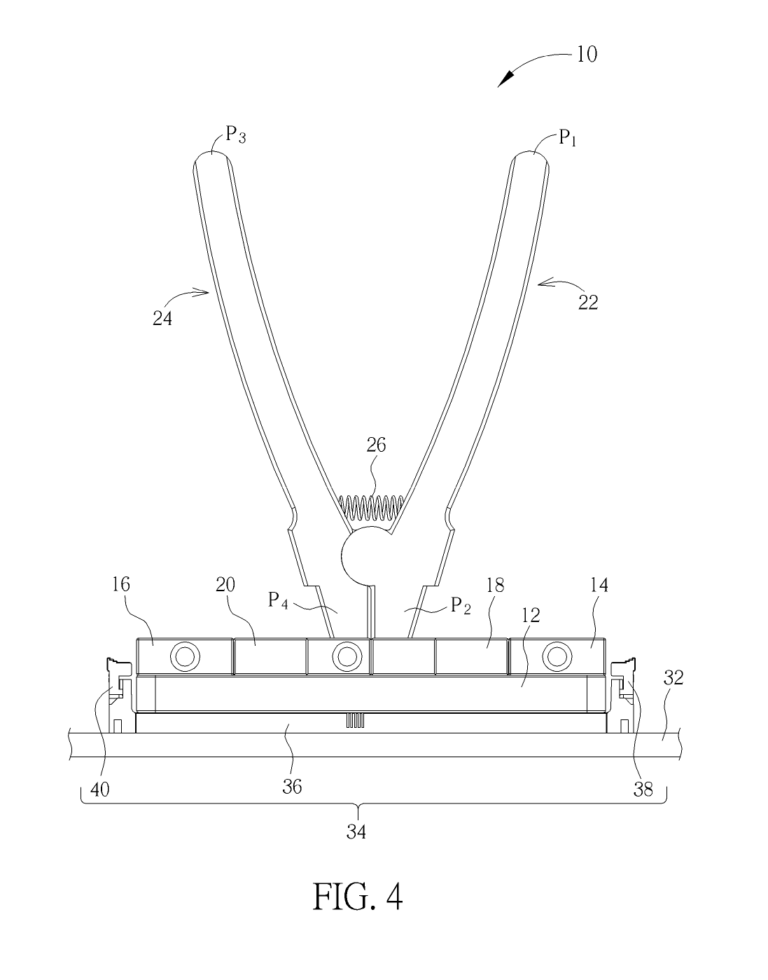

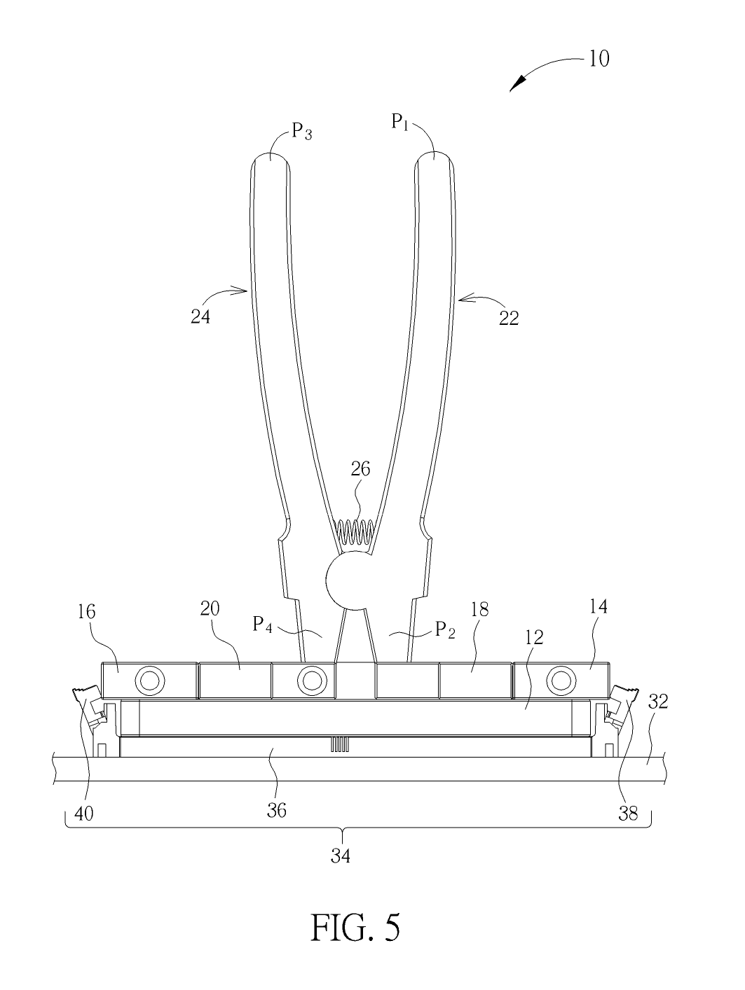

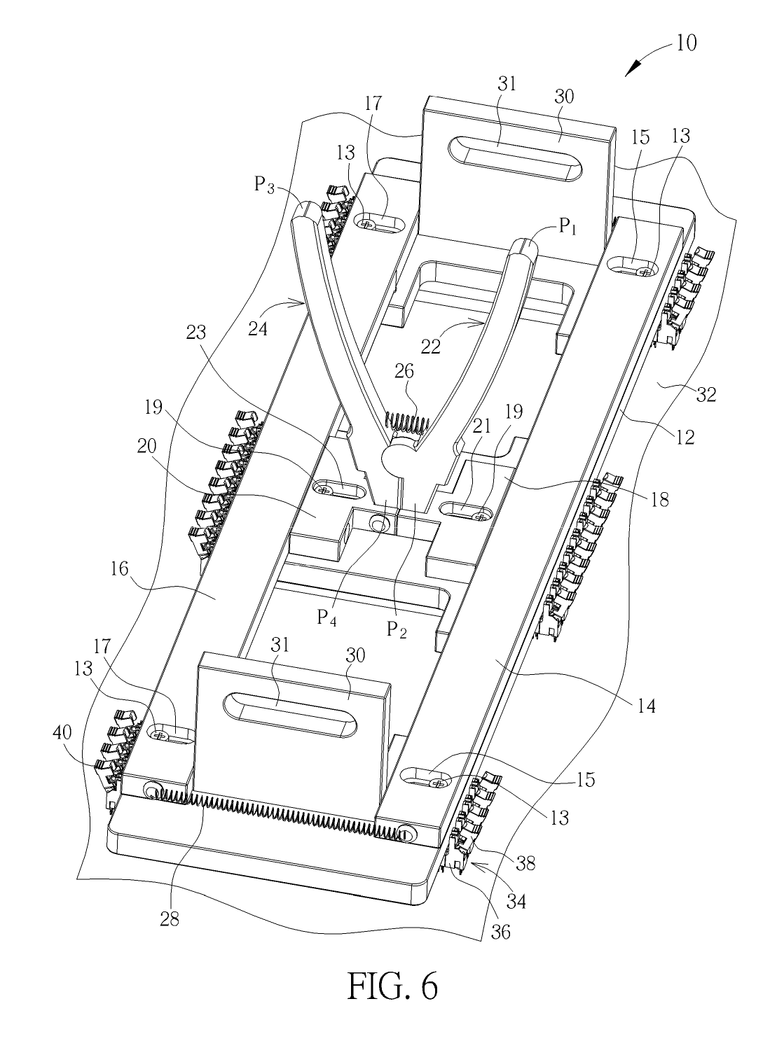

More detailed description for utilizing the latch release tool 10 to release a plurality of memory slot devices 34 on a main board 32 is provided as follows. Please refer to FIG. 3, FIG. 4, FIG. 5, and FIG. 6. FIG. 3 is a diagram of the latch release tool 10 in FIG. 2 being placed on a plurality of memory slot devices 34 on a main board 32. FIG. 4 is a side view of the latch release tool 10 in FIG. 3 being placed on the main board 32. FIG. 5 is a side view of the first strip block 14 and the second strip block 16 in FIG. 4 pushing a first latch 38 and a second latch 40 to the release position respectively. FIG. 6 is a diagram of the first strip block 14 and the second strip block 16 in FIG. 5 being separate from the first latch 38 and the second latch 40 respectively. Each memory slot device 34 (e.g. DIMM) includes a strip slot 36, the first latch 38, and the second latch 40. The first latch 38 and the second latch 40 are pivoted to two ends of the strip slot 36, so that the first latch 38 and the second latch 40 could rotate to the lock position to fix a memory device on the strip slot 36 or rotate to the release position to allow the memory device to be inserted into or detached from the strip slot 36. Furthermore, for clearly showing the mechanical design of the latch release tool 10, the limiting block 30 and the second spring 28 are omitted in FIG. 4 and FIG. 5.

When a user wants to utilize the latch release tool 10 to release the plurality of memory slot devices 34 on the main board 32, the user could place the latch release tool 10 on each strip slot 36 (as shown in FIG. 3). Subsequently, the user could exert force upon the first force applying end P₁ of the first handle 22 and the second force applying end P₃ of the second handle 24 to drive the first force applying end P₁ and the second force applying end P₃ to approach each other, for making the first handle 22 and the second handle 24 rotate (at this time, the first spring 26 is in a compressed state). Accordingly, with rotation of the first handle 22 and the second handle 24, the first driving end P₂ and the second driving end P₄ could push the first driving block 18 and the second driving block 20 from the position as shown in FIG. 4 outward to the position as shown in FIG. 5. During the aforesaid process, the first driving block 18 and the second driving block 20 could drive the first strip block 14 and the second strip block 16 to push each first latch 38 and each second latch 40 respectively, so that each first latch 38 and each second latch 40 could rotate from the lock position as shown in FIG. 4 to the release position as shown in FIG. 5 (at this time, the second spring 28 is in a stretched state).

After each first latch 38 and each second latch 40 are pushed respectively by the first strip block 14 and the second strip block 16 to rotate to the release position as shown in FIG. 5, the user could stop exerting force upon the first force applying end P₁ of the first handle 22 and the second force applying end P₃ of the second handle 24. At this time, the first spring 26 in the compressed state could provide elastic force to make the first forced applying end P₁ and the second force applying end P₃ away from each other, so as to make the first driving end P₂ and the second driving end P₄ pull the first driving block 18 and the second driving block 20 respectively to move inward. Simultaneously, the second spring 28 in the stretched state could also provide elastic force to pull the first strip block 14 and the second strip block 16 to move inward until the first driving block 18 and the second driving block 20 abut against each other and the first strip block 14 and the second strip block 16 abut against the limiting block 30 (as shown in FIG. 6), so that the first strip block 14 and the second strip block 16 could be separate from each first latch 38 and each second latch 40 respectively. In such a manner, the user could take the latch release tool 10 out of the main board 32 easily (e.g. grasping the limiting block 30 via the slot hole 31 and then lifting the latch release tool 10), so that the user could insert a memory device into the strip slot 36 and could utilize the latch release tool 10 to release memory slot devices on another main board.

It should be mentioned that the first spring 26, the second spring 28, and the limiting block 30 could be omitted for simplifying the mechanical design of the latch release tool 10. For example, the aforesaid return operation of the latch release tool 10 could be performed manually by the user without disposal of the first spring 26, the second spring 28, and the limiting block 30, or the latch release tool 10 could only have the second spring 28 disposed thereon to make the first strip block 14 and the second strip block 16 capable of returning the original position automatically. As for the related description for other derivative embodiments, it could be reasoned by analogy according to the aforesaid description and therefore omitted herein.

In summary, compared with the prior art in which the user must utilize his fingers to push each latch to the release position, the present invention utilizes the linkage mechanism composed of the handles, the driving blocks, and the strip blocks, to make the driving blocks move outward with rotation of the handles, so that the strip blocks could push the latches from the lock position to the release position. In such a manner, it is time-saving and effortless for the user to release the memory slot devices on the main board by utilizing the latch release tool provided by the present invention, so as to improve convenience of the memory installation operation of the main board. Furthermore, since the present invention does not require the user to utilize his fingers to push the latches, the latch release tool provided by the present invention could further solve the prior art problem that the memory slot device could damage easily due to excessive force exerted by the user, and could effectively prevent the user's fingers from being cut by the memory device accidentally.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A latch release tool for releasing a plurality of memory slot devices of a main board, each memory slot device comprising a strip slot, a first latch, and a second latch, the first latch and the second latch being pivoted to two ends of the strip slot respectively, the latch release tool comprising:
a baseboard having a first side and a second side opposite to the first side;
a first strip block movably disposed on the first side of the baseboard;
a second strip block movably disposed on the second side of the baseboard;
a first driving block movably disposed between the first strip block and the second strip block and connected to the first strip block;
a second driving block movably disposed between the first driving block and the second strip block and connected to the second strip block;
a first handle having a first force applying end and a first driving end, the first driving end being inserted into the first driving block; and
a second handle pivoted to the first handle and having a second force applying end and a second driving end, the second driving end being inserted into the second driving block, the first driving end and the second driving end respectively pushing the first driving block and the second driving block to move outward when the baseboard is placed on each strip slot and force acts on the first force applying end and the second force applying end to make the first handle and the second handle rotate relatively, for driving the first strip block and the second strip block to respectively push each first latch and each second latch so that each first latch and each second latch could rotate from a lock position to a release position.

2. The latch release tool of claim 1 further comprising:
a first spring connected to the first handle and the second handle, the first spring being for providing elastic force to make the first force applying end and the second force applying end away from each other and to make the first driving end and the second driving end respectively pull the first driving block and the second driving block to move inward, so as to drive the first strip block and the second strip block to separate from each first latch and each second latch respectively.

3. The latch release tool of claim 2 further comprising:
at least one second spring connected to the first strip block and the second strip block for providing elastic force to pull the first strip block and the second strip block to move inward, so as to make the first strip block and the second strip block separate from each first latch and each second latch respectively.

4. The latch release tool of claim 3 further comprising:
at least one limiting block disposed on the baseboard and located between the first strip block and the second strip block for abutting against the first strip block and the second strip block when the first strip block and the second strip block move inward.

5. The latch release tool of claim 4, wherein the at least one limiting block has a slot hole.

6. The latch release tool of claim 4, wherein the at least one limiting block is made of bakelite material.

7. The latch release tool of claim 1 further comprising:
at least one spring connected to the first strip block and the second strip block for providing elastic force to pull the first strip block and the second strip block to move inward so as to make the first strip block and the second strip block separate from each first latch and each second latch respectively.

8. The latch release tool of claim 7 further comprising:
at least one limiting block disposed on the baseboard and located between the first strip block and the second strip block for abutting against the first strip block and the second strip block when the first strip block and the second strip block move inward.

9. The latch release tool of claim 8, wherein the at least one limiting block has a slot hole.

10. The latch release tool of claim 1, wherein the first driving block and the second driving block are a T-shaped block respectively.

11. The latch release tool of claim 1, wherein the first driving block and the second driving block are movably disposed on the baseboard in a shaft-hole fitting manner.

12. The latch release tool of claim 1, wherein the first driving block and the second driving block are made of aluminum alloy material.

13. The latch release tool of claim 1, wherein the first strip block and the second strip block are movably disposed on the baseboard in a shaft-hole fitting manner.

14. The latch release tool of claim 1, wherein the baseboard, the first strip block, the second strip block, the first handle, and the second handle are made of bakelite material.
